(19) United States
(12) Patent Application Publication
(10) Pub. No.: US 2002/0030261 A1
(43) Pub. Date: Mar. 14, 2002

(54) Multi-flip-chip semiconductor assembly

(76) Inventors: Ruben A. Rolda JR., Baguio City (PH); Erwin R. Estepa, Baguio City (PH); Lani Guimbaolibot, Baguio City (PH)

Correspondence Address: Gary C. Honeycutt, Texas Instruments Incorporated, P.O. Box 655474, M/S 3999, Dallas, TX, 75265, US

(21) Appl. No.: 09/737,710

(22) Filed: Dec. 18, 2000

Related U.S. Application Data
(60) Provisional application No. 60/172,186, filed on Dec. 17, 1999.

(51) Int. Cl. H01L 23/02; H01L 21/44; H01L 21/48

(52) U.S. Cl. 257/685; 438/108

(57) ABSTRACT

A semiconductor assembly comprising first and second chips, each having an active surface including an integrated circuit and a plurality of input/output contact pads; an interposer of electrically insulating material having a plurality of electrically conductive paths extending through said interposer from the first surface to the second surface, forming electrical terminals on each of said surfaces; said interposer being disposed between said active surfaces of said first and second chips; connections between each of said contact pads of said first chip to selected terminals on said first interposer surface, respectively, and between each of said contact pads of said second chip to selected terminals on said second interposer surface, respectively; and said interposer further having electrical terminals for interconnecting said chips to other parts.

### FIELD OF THE INVENTION

The present invention is related in general to the field of semiconductor devices and processes, and more specifically to assembly methods for integrated circuit chips resulting in multichip devices in a single package, having advanced performance characteristics and fast turnaround development times.

### DESCRIPTION OF THE RELATED ART

It is advantageous for many applications of semiconductor devices to arrange the needed devices in close proximity, even in a cluster. When only two, or few more, semiconductor chips are needed, various arrangements have been proposed in order to achieve the desired proximity, and to enable a minimization of required space. Typically, these arrangements are assemblies of semiconductor chips on a substrate, with or without a specific encapsulation. For these arrangements, the term “multichip module” is commonly used. For an encapsulated assembly, the term “multichip package” has been introduced. For many years, there has been a rather limited market for multichip modules and multichip packages, but driven by the rapidly expanding penetration of integrated circuit applications, this market is recently growing significantly in size. In order to participate in this market, though, the multichip products have to meet several conditions.

The multichip product has to offer the customer performance characteristics not available in single-chip products. This means, the multichip product has to leapfrog the development of single-chip product.

The multichip product has to be available to the customer at short notice. This means, the multichip product should use readily available components and fabrication methods.

The multichip product has to offer the customer a cost advantage. This means, the design and fabrication of the multichip product has to avoid unconventional or additional process steps.

The multichip product has to offer low cost-of-ownership. This means, it has to operate reliably based on built-in reliability.

Numerous multichip packages have been described in publications and patents. For instance, U.S. Pat. No. 4,862,322, Aug. 29, 1989 (Bickford et al.) entitled “Double Electronic Device Structure having Beam Leads Solderlessly Bonded between Contact Locations on each Device and Projecting Outwardly from Therebetween” describes a structure of two chips facing each other, in which the input/output terminals are bonded by beam leads. The high cost, however, of materials, processing and controls never allowed the beam lead technology to become a mainstream fabrication method.

In U.S. Pat. No. 5,331,235, Jul. 19, 1994 (H. S. Chun) entitled “Multi-Chip Semiconductor Package”, tape-automated bonding plastic tapes are used to interconnect two chips of identical types, facing each other, into pairs. One or more of these pairs are then assembled into an encapsulating package, in which the plastic tapes are connected to metallic leads reaching outside of the package to form the leads or pins for surface mount and board attach. The high cost of the plastic tapes and the lack of batch processing kept the technology of tape-automated bonding at the margins of the semiconductor production.

Several proposals have been made of multichip devices in which two or more chips are arranged side by side, attached to a supporting substrate or to leadframe pads. An example is U.S. Pat. No. 5,352,632, Oct. 4, 1994 (H. Sawaya) entitled “Multichip Packaged Semiconductor Device and Method for Manufacturing the Same”. The chips, usually of different types, are first interconnected by flexible resin tapes and then sealed into a resin package. The tapes are attached to metallic leads which also protrude from the package for conventional surface mounting. Another example is U.S. Pat. No. 5,373,188, Dec. 13, 1994 (Michii et al.) entitled “Packaged Semiconductor Device including Multiple Semiconductor Chips and Cross-over Lead”. The chips, usually of different types, are attached to leadframe chip pads; their input/output terminals are wire bonded to the inner lead of the leadframe. In addition, other leads are used under or over the semiconductor chips in order to interconnect terminals which cannot be reached by long-spanned wire bonding. Finally, the assembly is encapsulated in a plastic package. In both of these examples, the end products are large, since the chips are placed side by side. In contrast, today's applications require ever shrinking semiconductor products, and board consumption is to be minimized. U.S. Pat. No. 5,438,224, Aug. 1, 1995 (Papageorge et al.) entitled “Integrated Circuit Package having a Face-to-Face IC Chip Arrangement” discloses an integrated circuit (IC) package with a stacked IC chip arrangement placed on a circuit substrate. Two chips are positioned face to face, with a substrate made of tape-automated bonding tape or flex circuit interposed between the chips to provide electrical connection among the terminals of the flip chip and external circuitry; a separate mechanical support is needed for the assembly. In addition to this cost, fabrication is difficult due to the lack of rigid support for the chips.

U.S. Pat. No. 5,770,480, Jun. 23, 1998 (Ma et al.) entitled “Method of Leads between Chips Assembly” increases the IC density by teaching the use of leadframe fingers to attach to the bond pads of multiple chips employing solder or conductive bumps. While in the preferred embodiments both chips of a set are identical in function, the method extends also to chips with differing bond pad arrangements. In this case, however, the leadframe needs customized configuration and non-uniform lengths of the lead fingers, especially since the use of bond wires is excluded. The manufacture of these so-called variable-leads-between-chips involves costly leadframe fabrication equipment and techniques. In addition, a passivation layer is required, to be disposed between the two chips and the customized lead fingers, in order to prevent potential electrical shorts, adding more material and processing costs.

In two recent U.S. patent applications, Ser. No. 09/396,338, filed Sep. 15, 1999, and Ser. No. 09/396,632, filed Sep. 15, 1999, to which the present invention is related, multichip semiconductor assemblies are described, which are based on specially formed metallic leadframes. They do not lend themselves to high lead count devices or to products with thin outline, needed on most handheld applications. Further, the need for special leadframes is always a costly solution with limited suppliers.

An urgent need has therefore arisen for a coherent, low-cost method of fabricating multichip packages based on available chip designs and assembly and encapsulation techniques. The method should be flexible enough to be applied for different semiconductor product families and a wide spectrum of design and process variations, should add no additional cost to the existing fabrication methods, and deliver high-quality and high-reliability products. Preferably, these innovations should be accomplished while shortening production cycle time and increasing throughput.

### SUMMARY OF THE INVENTION

The present innovation provides a method for increasing integrated circuit density and creating novel performance characteristics by forming a multichip device comprising a stack of typically two semiconductor chips with an insulating interposer disposed between the chips. The interposer has a plurality of conductive paths and contact ports. The device is fabricated by connecting each of the chip contact pads to one of the interposer ports, respectively, using solder ball reflow. The gaps thus created may be filled with polymeric material. Solder balls of typically different size and reflow temperature are attached to the interposer for connection of the assembly to other parts.

The chips of the stack can be found in many semiconductor device families; preferred embodiments of the invention include chip pairs of digital signal processors (DSPs) and static random-access memories (SRAMs), application-specific integrated circuits (ASICs) and SRAMs, dynamic random-access memories (DRAMs) and SRAMs, FLASH memories and SRAMs, logic and analog devices, and application-specific products (ASP) and wireless products. In these examples, each chip of the sets is readily available. If one would endeavor to duplicate the performance of the stacked chips by a single chip, it would not only require precious design and development time, but would result in large-area chips of initially lower fabrication yield, and large-area packages consuming valuable board space. Consequently, the invention helps to alleviate the space constraint of continually shrinking applications such as cellular communications, pagers, hard disk drives, laptop computers and medical instrumentation.

Furthermore, the invention uses multi-level interconnect interposers with solder connections to the outside world. The modules based on these interposers offer high numbers of connections to other parts (for example, between 300 and 1000 and more).

Other variations of the invention include stacks of chips identical in function, such as a pair of DRAMs designed for flip-chip assembly by solder reflow. In order to minimize thermomechanical stress on the solder joints, it is preferable that the size of the solder connections as well as the coefficients of thermal expansion of the various assembly components are selected based on stress modeling using finite element analysis.

The multichip assembly of the present invention has the additional benefit of reducing trace inductance by shortening conductive paths. This effort is supported by sharing signals on a common conductor whenever possible. The signal path is considerably reduced compared to a simple assembly of two individual packages next to each other, just connected by conductive paths on a printed substrate or circuit board.

According to the first embodiment of the invention, the gaps between the assembled chips and the interposer are underfilled with epoxy-based polymer material, significantly reducing thermomechanical stress in the solder joints.

According to the second embodiment of the invention, the assembly is encapsulated in a molded package. The preferred method is transfer molding using the so-called “3-P” technology. Emphasis is placed on cleanliness of the molding compound by prepacking and sealing it in plastic forms which are only ruptured at time of usage, and on preventing the deleterious adhesion to the mold cavity walls of the molding compound by covering thin continuous plastic films over the mold walls.

It is an aspect of the present invention to provide a low-cost method and system for packaging two or more chip (multichip) devices in thin overall package profile by disposing an insulating interposer, integral with a plurality of conductive paths, between the chips of a stack. The conductive paths extend through the interposer from one surface to the opposite surface, and also provide the connection of the assembled chips to the outside world.

Another aspect of the invention is to be flexible with regard to the size, configuration, material and reflow temperature of the solder materials used. In order to simplify the assembly process of a module, solder materials with different reflow temperatures may be used.

Another aspect of the invention is to stagger the positioning of the solder balls connecting the second chip to the interposer relative to the corresponding solder balls connecting the first chip to the interposer, thereby reducing stress between the chips.

Another aspect of the present invention is to enhance production throughput by the self-aligning characteristic of solder attachment, especially when considering that the solder joints have uniform height independent of shape an volume.

Another aspect of the present invention is to improve product quality by promoting solder wetting and choosing the process temperatures so that multiple solder reflows can be avoided.

Another aspect of the invention is to provide reliability assurance through in-process control at no extra cost.

Another aspect of the invention is to introduce assembly concepts which are flexible so that they can be applied to many families of semiconductor products, and are general so that they can be applied to several future generations of products

Another aspect of the invention is to minimize the cost of capital investment and to use the installed fabrication equipment base.

These aspects have been achieved by the teachings of the invention concerning the modifications of the selected solders, arrangements of chips, and flexible assembly methods. Various modifications have been employed for the assembly and encapsulation of modules.

The technical advances represented by the invention, as well as the objects thereof, will become apparent from the following description of the preferred embodiments of the invention, when considered in conjunction with the accompanying drawings and the novel features set forth in the appended claims.

### BRIEF DESCRIPTION OF THE DRAWINGS

FIG. 1 is a simplified and schematic cross section of a semiconductor chip assembly based on solder reflow and underfill, with solder connection to other parts, according to the first embodiment of the invention.

FIG. 2 is a simplified and schematic cross section of a semiconductor chip assembly based on solder reflow, encapsulated in a molded package, according to the second embodiment of the invention.

FIG. 3 shows the cross section of a schematic and simplified portion of an interposer.

### DETAILED DESCRIPTION OF THE PREFERRED EMBODIMENTS

The present invention is related to an arrangement of two or more semiconductor integrated circuit chips in a multichip assembly. As defined herein, the term “multichip” refers to a set of two or more semiconductor integrated circuit chips which are in close proximity and electrically connected together so that they function as a unit. Commonly, they are also physically coupled by being assembled on a substrate or board. In another embodiment of the invention, they are encapsulated in a package. In one variation of the invention, the chips of a set are dissimilar relative to their size, design, and function; in another variation, they are identical.

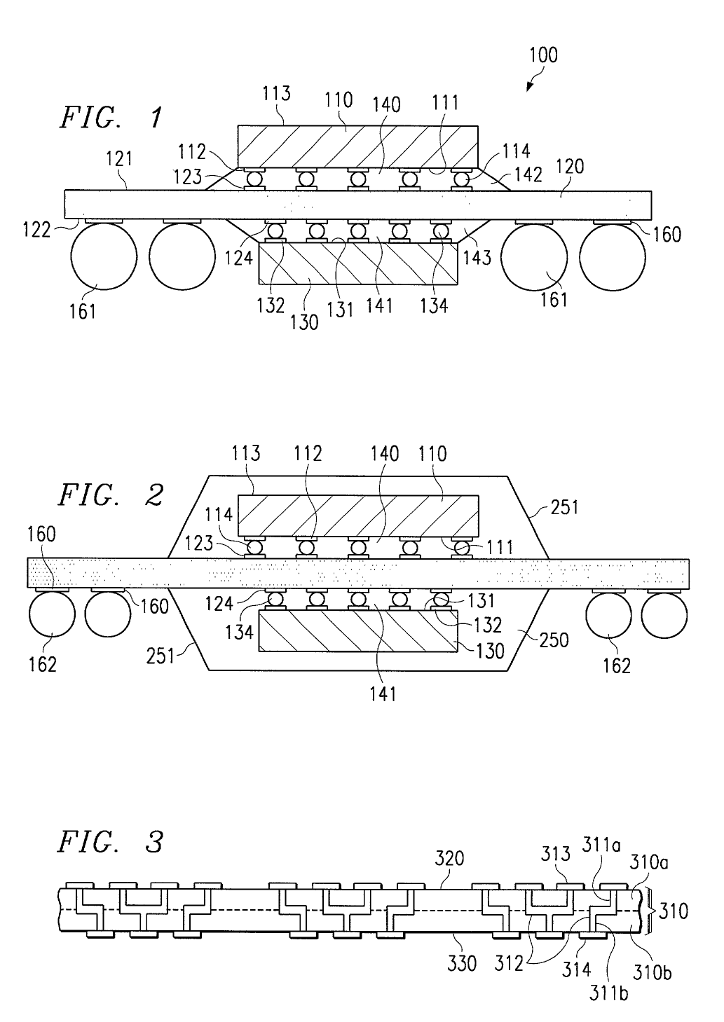

FIG. 1 is a simplified cross sectional view of a semiconductor multichip assembly that is generally designated 100, according to the first embodiment of this invention. The assembly comprises a set of two semiconductor integrated circuit (IC) chips. One or both may be made of silicon, silicon germanium, gallium arsenide or any other semiconductor material used in electronic device production. The thickness is typically in the range from 200 to 400 μm. The first chip 110 has an active surface 111 which includes the integrated circuit and a plurality of input/output contact pads 112. Chip 110 further has a passive surface 113.

Chip 110 is facing with its active surface 111 the interposer 120. The interposer is made of electrically insulating material and has a plurality of electrically conductive paths extending through the interposer from its first surface 121 to its second surface 122 (the conductive paths are not shown in FIG. 1). In FIG. 1, the interposer comprises a plurality of terminals 123, located on first surface 121, and terminals 124, located on second surface 122. By disposing the interposer between the chips of the set, it functions to interconnect the ICs of the module.

Interposers have been used to provide electrical connection between solder-bumped semiconductor chips and assembly (P.C.) boards, and also some mechanical flexibility to help preventing solder ball cracking under mechanical stress due to thermal cycling. The interposer is preferably made of compliant material, such as tape, Kapton™ film, polyimide, or other plastic material, and may contain single or multiple layers of patterned conductors. In this fashion, the flexibility of the base material provides a stress buffer between the thermally mismatched semiconductor chip and the P.C. board, and will relieve some of the strain that develops in the chip solder balls in thermal cycling. Alternatively, an interposer may be made of epoxies, FR-4, FR-5, or BT resin. An interposer can further provide a common footprint to industry standards for chip-size packages and may minimize the number of inputs and outputs by allowing common connections for power and ground within the interposer.

Interposers are commercially available, for instance Novaclad® and ViaGrid® from Sheldahl, Inc., Northfield, Minn. They are typically fabricated by laminating alternative films of electrically insulating and electrically conducting materials into one coherent layer. Connections through individual insulating films are made by laser drilling and metal refilling or plating, and patterning of the conductive films is achieved by ablation or etching. There are numerous designs and variations of interposers available. An example is schematically shown in cross section in FIG. 3. FIG. 3 is a finished interposer with a five-layered structure. Originally separate insulating film 310a, having laser-drilled or etched via holes 311a filled or plated with metal such as copper, has been fused with insulating film 310b, having laser-drilled via holes 311b filled or plated with metal such as copper, to form interposer layer 310. Metal film portions 312, needed to selectively interconnect via holes 311a and 311b, were originally one coherent metal film (such as copper) laminated onto one of the insulating films for patterning (by ablating or etching) into the film portions. Terminals 313 on surface 320 and terminals 314 on surface 330 of interposer 310 are also typically made of copper, often with a protective flash of gold.

Each of the input/output contact pads 112 on the active surface 111 of chip 110 is connected to the terminals 123 on the first surface 121 of the interposer 120, respectively, by solder balls 114.

As used herein, the term solder “ball” does not imply that the solder contacts are necessarily spherical; they may have various forms, such as semispherical, half-dome, truncated cone, or generally bump, or a cylinder with straight, concave or convex outlines. The exact shape is a function of the deposition technique (such as evaporation, plating, or prefabricated units) and reflow technique (such as infrared or radiant heat), and the material composition. Generally, a mixture of lead and tin is used; other materials include indium, alloys of tin/indium, tin silver, tin/bismuth, or conductive adhesive compounds. The melting temperature of the solder balls used for chip 110 may be different from the melting temperature of the solder balls used for the other chip, or the solder balls used for connecting the module to the outside world. Several methods are available to achieve consistency of geometrical shape by controlling amount of material and uniformity of reflow temperature. Typically, the diameter of the solder balls ranges from 0.1 to 0.5 mm, but can be significantly larger.

In order to insure reliable attachment of the solder to the chip contact pads and the interposer terminals, preparations have to be taken for achieving proper wetting. The chip contact pads 112 may be covered by layers of a refractory metal (such as chromium, molybdenum, titanium, tungsten, or titanium/tungsten alloy) and a noble metal (such as gold, palladium, platinum or platinum-rich alloy, silver or silver alloy). Interposer terminals 123 may have a flash of gold.

The second chip 130 in FIG. 1 has an active surface 131 which includes the integrated circuit and a plurality of input/output contact pads 132. Active surface 131 of chip 130 also faces the interposer 120. Each of the input/output contact pads 132 on the active surface 131 is connected to the second surface 122 of the interposer 120, respectively, by. solder balls 134.

As shown in FIG. 1, chips 110 and 130 are spaced apart from the interposer 120 by gaps 140 and 141, respectively. The solder bump interconnections extend across the gap and connect contact pads on the IC chips to contact pads on the interposer to attach the chips and then conduct electrical signals, power and ground potential to and from the chips for processing. There is a significant difference between the coefficient of thermal expansion (CTE) between the semiconductor material used for the chips and the material typically used for the interposer; for instance, with silicon as the semiconductor material (CTE=2.3 ppm/° C.) and polyimide as interposer insulator material (CTE˜25 ppm/° C.), the difference in CTE is about an order of magnitude.

As a consequence of the CTE difference, mechanical stresses are created when the assembly is subjected to thermal cycling during use or testing. These stresses tend to fatigue the solder bump interconnections, resulting in cracks and thus eventual failure of the assembly. Finite element analysis has shown that thermomechanical stresses can be minimized when the solder balls connecting the second chip 130 to the interposer 120 are staggered rather than aligned with respect to corresponding solder balls connecting the first chip 110 to the interposer.

In addition, in order to strengthen the solder joints without affecting the electrical connection, the gap is customarily filled with a polymeric material which encapsulates the bumps and fills any space in the gap between the semiconductor chip and the substrate.

The encapsulant is typically applied after the solder bumps are reflowed to bond the integrated circuit a chips to interposer. A polymeric precursor, sometimes referred to as the “underfill”, is dispensed onto the substrate adjacent to the chip and is pulled into the gap by capillary forces. Typically, the polymeric precursor comprises an epoxy-based material filled with silica and anhydrides. The precursor is then heated, polymerized and “cured” to form the encapsulant. It is well known in the industry that the elevated temperature and the temperature cycling needed for this curing can also create mechanical stresses which can be detrimental to the chip and the solder interconnections.

Consequently, whenever these assemblies undergo temperature excursions, the swings of increasing and decreasing temperatures induce different expansions and contractions in the materials couples to each other, causing tensile and compressive stresses to build up in the component parts. The underfilling method preferred by this invention has been described in U.S. patent application Ser. No. 60/084,440, filed on May 6, 1998.

Gaps 140 and 141 are filled with polymeric encapsulants 142 and 143, respectively, that extend over the interposer about the perimeter of the respective chips. The main purpose of encapsulants 142 and 143 is a reduction of mechanical stress in the assembly; another purpose is the protection of the active chip surface.

It is advantageous to encapsulate the finished multichip assembly in a molded package. As an example, FIG. 2 shows a schematic cross section of this second embodiment of the invention. If packages with very thin profile have to be produced, materials having very low viscosity and high adhesion should be used. They are best processed by the “3-P” molding technology. According to this method, clean molding materials are prepacked and sealed in plastic forms (for instance, in elongated, so-called “pencil” shape) which are only ruptured at time of usage. The deleterious adhesion to the mold cavity walls of the molding compound is prevented by covering the walls with thin continuous plastic films. Suitable epoxy-based thermoset resins or silicone-based elastomerics are commercially available from Sin Etsu Chemical Corporation, Japan, or Kuala Lumpur, Malaysia, or from Sumitomo Bakelite Corporation, Japan, or Singapore, Singapore. These materials also contain the appropriate fillers needed for shifting the coefficient of thermal expansion closer to that of silicon, and for enhancing the strength and flexibility of the molding material after curing.

The molding temperature (usually from 140 to 220° C.) has to be selected such that is lower than the reflow temperature of solder balls 114 and 134. Even minute spaces, for instance around and between the solder balls 114 and 134, can be reliably filled with molding material. This means, the process step of underfilling the gaps between the chips and the interposer described above, may be omitted since it is substituted by the molding process step. Voids or other cosmetic defects, are eliminated, and mechanical stress on the solder joints is minimized by the molding process.

After molding and curing the mold compound 250, the multichip module obtains the contours generally designated 251 in FIG. 2, which are determined by the product specifications.

As indicated in FIGS. 1 and 2, the interposer has electrical terminals 160 to interconnect the chips of the multichip set to other parts. The “other parts” typically include printed circuit boards, motherboards, or other electronic devices. Commonly, solder materials such as solder balls 161 and 162, respectively, are attached to terminals 160. Since this solder material is applied as the last fabrication step, it preferably has a lower reflow temperature than the solder balls used for chip attachment. Also, the solder balls or solder connections may be of larger geometrical size. Usually, however, they have a smaller diameter than the contour of the molded module, which necessitates either indentations into the assembly board for proper positioning of the molded module, or local elevations of the board for the solder attachment sites.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the IC chips used for the chip set may have different thicknesses. As another example, stress reduction by staggering the solder connections may be maximized in order to eliminate the need for stress reduction by underfilling. It is therefore intended that the appended claims encompass any such modifications or embodiments.

We claim:

1. A semiconductor assembly comprising:
first and second chips, each having an active surface including an integrated circuit and a plurality of input/output contact pads;
an interposer of electrically insulating material having a plurality of electrically conductive paths extending through said interposer from the first surface to the second surface, forming electrical terminals on each of said surfaces;
said interposer being disposed between said active surfaces of said first and second chips;
connections between each of said contact pads of said first chip to selected terminals on said first interposer surface, respectively, and between each of said contact pads of said second chip to selected terminals on said second interposer surface, respectively; and
said interposer further having electrical terminals for interconnecting said chips to other parts.

2. The assembly according to claim 1 wherein said interposer is selected from a group consisting of electrically insulating elastic, inelastic, and flexible materials including polymers, polyimides, epoxies, FR-4, FR-5, and BT resin.

3. The assembly according to claim 1 wherein at least one of said chips comprises silicon, silicon germanium, gallium arsenide or any other semiconductor materials used in electronic device production.

4. The assembly according to claim 1 wherein said chips comprise chips of different integrated circuit types.

5. The assembly according to claim 1 wherein said chips comprise chips of identical integrated circuit types.

6. The assembly according to claim 1 wherein said connections between said contact pads and said terminals comprise solder balls.

7. The assembly according to claims 6 wherein said solder balls are selected from a materials group consisting of tin/lead, tin/indium, tin/silver, tin/bismuth, and conductive adhesive compounds.

8. The assembly according to claim 6 wherein said solder balls connecting said first chip contact pads to said interposer first surface terminals are different in size, material and reflow temperature from said solder balls connecting said second chip contact pads to said interposer second surface terminals.

9. The assembly according to claim 1 wherein said solder balls attached to said interposer ports suitable for connecting to other parts are different in size, material and reflow temperature from said solder balls attached to said first and second chips.

9. The assembly according to claim 6 wherein said chips are mounted onto said interposer surfaces spaced apart by gaps.

10. The assembly according to claim 6 wherein said solder balls connecting said second chip to said interposer are staggered with respect to corresponding solder balls connecting said first chip to said interposer, thereby reducing stress between the chips.

11. The assembly according to claim 6 further including a polymeric encapsulant filling said gaps, whereby thermo-mechanical stress levels are reduced to values safe for operating said assembly.

12. The assembly according to claim 11 wherein polymeric encapsulant comprises an epoxy-based material filled with silica and anhydrides.

13. The assembly according to claim 1 wherein said terminals for interconnection to other parts further comprise solder balls attached to said terminals.

14. The assembly according to claim 13 wherein said solder balls suitable for connecting to other parts are different in size, material and reflow temperature from said solder balls attached to said first and second chip contact pads.

15. The assembly according to claim 1 further including an encapsulation of said assembly in a molded package.

16. The assembly according to claim 15 wherein said molded package comprises an epoxy-based compound filled with silica and anhydrides.

17. A method for fabricating an assembly of first and second semiconductor chips, each having an active surface including an integrated circuit and a plurality of input/output contact pads, comprising the steps of:
disposing an interposer between said active surfaces for interconnecting said integrated circuits, said interposer made of insulating material having first and second surfaces and a plurality of conductive paths and terminals;
connecting each of said contact pads of said first chip by solder ball reflow to selected terminals on said first surface of said interposer, respectively, mounting said first chip to said interposer; and
connecting each of said contact pads of said second chip by solder ball reflow to selected terminals on said second surface of said interposer, respectively, mounting said second chip to said interposer.

18. The method according to claim 17 further comprising the steps of spacing said first chip apart from said interposer by a gap, and spacing said second chip apart from said interposer by a gap.

19. The method according to claim 18 further comprising the step of filling said gaps with a polymeric precursor and supplying thermal energy for curing said polymeric precursor to form a polymeric encapsulant.

20. The method according to claim 17 further comprising the step of encapsulating the assembly in a molded package.

21. The method according to claim 17 further comprising the step of attaching solder balls to said interposer terminals suitable for connecting to other parts.
